(19) United States
(12) Patent Application Publication
(10) Pub. No.: US 2009/0166654 A1
(43) Pub. Date: Jul. 2, 2009

(54) LIGHT-EMITTING DIODE WITH INCREASED LIGHT EFFICIENCY

(76) Inventors: Zhiyin Gan, Shanghai (CN); Sheng Liu, Shanghai (CN); Pei Wang, Wuhan (CN); Kai Wang, Yuyao (CN)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/967,817

(22) Filed: Dec. 31, 2007

(51) Int. Cl. H01L 33/00

(52) U.S. Cl. 257/98; 257/E33.001

(57) ABSTRACT

A novel light-emitting diode structure is proposed wherein the epitaxial layers are cleaved to micro-units to suppress transverse propagation of light generated in active layer and improve light extraction efficiency. Further enhancement in light output will be obtained by introducing a light extraction layer with microstructures or directly structuring the top surface of each micro-unit. Another advantage of the method is effective thermal dissipation due to the hollowed-out pattern and possible buried heat conductive materials.

### FIELD OF THE INVENTION

The invention concerns a design to improve the light extraction efficiency of light-emitting diodes.

### BACKGROUND OF THE INVENTION

The light extraction efficiency of light-emitting diodes is low primarily due to the large refractive index difference between the semiconductor material and the surrounding media. For example, the refractive indexes of GaN and the air are 2.4 and 1, respectively. The critical angle of total internal reflection is about 25°, thus the light extraction efficiency of conventional GaN-based light-emitting diodes is only a few percent. In addition, Fresnel loss of the interface and absorption in the active layer, absorption in the area of the contact and absorption in the substrate also cause reduction of the light extraction. Measures to improve the light extraction include avoiding total internal reflection, enlarging escape cone or creating more escape cones, avoiding absorption and reducing Fresnel loss.

One method used to avoid total internal reflection is to make the top surface of the LED chip structured to alter the incidence angle.

U.S. Pat. No. 3,739,217 has disclosed that roughening surface of the LED chip by chemical or mechanical means will bring an increase in light extraction efficiency. At first incidence light will escape from a rough surface at approximately the same rate as a flat surface. A rough surface, however, will cause a random reflection, which makes the reflected light have a greater chance of escaping on the second and succeeding times. This is different from the case of a flat surface which holds the same reflection angles and makes the total internally reflected light never escape. In “Appl. Phys. Lett. 84, 855 (2004)” the light extraction of a roughened GaN-based LED was increased twofold to threefold compared to that of a conventional one. Since the surface morphology of a roughened LED is irregular, the light extraction is not easily controllable and predictable. In addition, the potential in light extraction after the regular packaging for the roughened LED is not fully realized, as discovered by some professionals in the community.

The computer simulations reveal that well-regulated microstructures on the top surface of the LED may result in an enhancement of light extraction. The non-plane surface of the microstructures allows a greater portion of the light to strike the interface at an angle less than critical angle. U.S. Pat. No. 6,649,939 introduces a light exit-side surface covered with a plurality of truncated pyramids to improve the light output. U.S. Pat. No. 7,135,709 also proposes that surface structures which comprise of regularly arranged n-sided prisms, pyramids or frusta of pyramids, cylinders, cones, frusta of cones and the like will cause a visible improvement in the decoupling of light.

Another approach to improve light extraction is to adopt geometrically deformed LED chips.

In U.S. Pat. No. 5,087,949 an LED with diagonal faces is proposed. There may be twelve escape cones, and internal reflections of light which do not escape first time have a larger probability to be reflected into an escape cone. This provides a twice improvement in extraction efficiency compared to a conventional LED chip. In U.S. Pat. No. 7,268,371, it is disclosed that the sidewalls of the LED chip are formed at certain angles relative to vertical to increase light output. The oblique side surfaces will reflect light to the top surface within the critical angle and also allow the light trapped by total internal reflection from the top surface to escape out of the sidewalls. A practically shaped LED chip consisting of a truncated-inverted-pyramid geometry AlGaInP/GaP LED is described in “Appl. Phys. Lett. 75, 2365 (1999)”. Light is generated at the base of the pyramid and extracted at a fewer number of reflections within the chip. It achieved a peak external efficiency of 55% at 650 nm.

Both surface structuring and chip shaping provide improvement in light extraction to some extent. Most of light generated in active region, however, is still trapped inside the chip due to its transverse (parallel to the epitaxial layers) propagation. Surface structuring is just advantageous to extraction of light impinging on the top surface. Geometrically deformed chip structure will make some transversely transmitted light be reflected to the top surface, but much light is absorbed because of the long path through the entire chip area. Therefore, the effective extraction efficiency obtained is limited in such a structure.

It is, therefore, significant to propose more useful methods for improving the light extraction efficiency of an LED.

### SUMMARY OF THE INVENTION

It is an object of the present invention to propose a light-emitting diode having high light extraction efficiency.

The light-emitting diode described above comprises a substrate and an epitaxial layer including a buffer layer, an n-contact layer, an active layer for generating light and a p-contact layer grown on the substrate in sequence. The epitaxial layer is cleaved into micro-units to suppress light transverse propagation and direct light towards the top or side surfaces through a short path. The micro-units can take any conceivable form, such as trapeze form strips array, truncated pyramids array, truncated cones array, cubes array, certain free-form optics array and the like. The depth of cleaving is not constant. To extract light striking on the top interface more effectively, microstructures are formed on the top surface of the micro-units or the light extraction layer deposited on the epitaxial layer. Some feasible shapes of said microstructures include regular micro-lens array, pyramids array, cones array, tetrahedrons array, concave tapers, concave torus, concave cylinder, certain free-form optics array and the like. A thickness of said light extraction layer is greater than 2 microns.

Another light-emitting diode structure would be gained by bonding the chip with cleaved epitaxial layer onto a new conductive substrate and then removing the former substrate. Then the microstructures are made as described above.

Most of light generated in active region escapes from the top or lateral surfaces of each micro-unit, however, the light escaping out of the lateral surface has a certain probability to enter into the adjacent micro-units and never escape. The more micro-units are formed, the more obvious is this effect. To solve this problem, an optimal design of the shapes and oblique angles of the sidewalls of the micro-units should be conducted. It is a better method that a reflected film is deposited on the lateral sides of the micro-units, which will prevent the light from entering into other micro-units and orient the light towards the top surface. In addition, the method of embedding other low refractive-index materials into the gaps between the micro-units could be adopted. Since the light of each micro-unit could escape furthest, the light extraction efficiency is independent of chip size, that is, it will lead to a completely scalable chip design, making large chips achievable, which will innovate the current understanding that the smaller the chips, more optical output one can obtain. Further, an optimal stress level may be achieved so that the long term reliability of the large chips can be assured by minimizing the thermal mismatch globally and locally.

In terms of the optical output, there are a number of parameters in terms of the shape of the micro-units and microstructures that lead to an optimization of the light output, as has been investigated in detail through ray-tracing simulations.

The present invention is thus based on a combination of cleaving the epitaxial layer into micro-units, which suppresses the traverse propagation of the light and directs the light to the top surface of the LED chip through a short path, and top surface structuring of the semiconductor, which contributes to the output efficiency of the light striking on the top interface. Although the active layer may be partially fragmented, causing applicable active layer area to decrease, the overall light output is offset by the improvement in light extraction. The present invention also comprises the advantage of effective heat dissipation due to the hollowed-out pattern or possibly buried heat conductive materials in the hollowed pattern to help heat dissipation, and the likely stress isolation, as described in the last paragraphy. Besides, this structure is comparatively simple to realize with only additional lithography process steps and subsequent dry etching or other applicable etching processes.

Exemplary embodiments of the present invention are described below in greater detail with reference to the drawings.

### BRIEF DESCRIPTION OF THE DRAWINGS

FIG. 1 is a schematic diagram showing the vertical layer structure of a conventional GaN-based light-emitting diode.

FIG. 2 is a cross-section of a light-emitting diode with cleaved epitaxial layer.

FIG. 3 is a cross-section view similar to FIG. 2 but with different cleaving depth.

FIG. 4 illustrates a top view of an alternative embodiment in the plane of the chip.

FIG. 5 is a cross-section of a light extraction layer introduced with micro structures.

FIG. 6 illustrates a process of forming an n-side-up light-emitting diode.

FIG. 7 is a cross-section of an n-side-up light-emitting diode with cleaved epitaxial layer.

FIG. 8 is a cross-section similar to FIG. 6 but the sidewalls of each micro-unit are reflected.

FIG. 9 is a schematic to illustrate an embodiment of the shape of one single micro-unit.

FIG. 10, FIG. 11 is a cross-section and top view of an alternate embodiment of microstructures on one single micro-unit respectively in the plane of the chip.

### DETAILED DESCRIPTION OF THE PREFERRED EMBODIMENTS

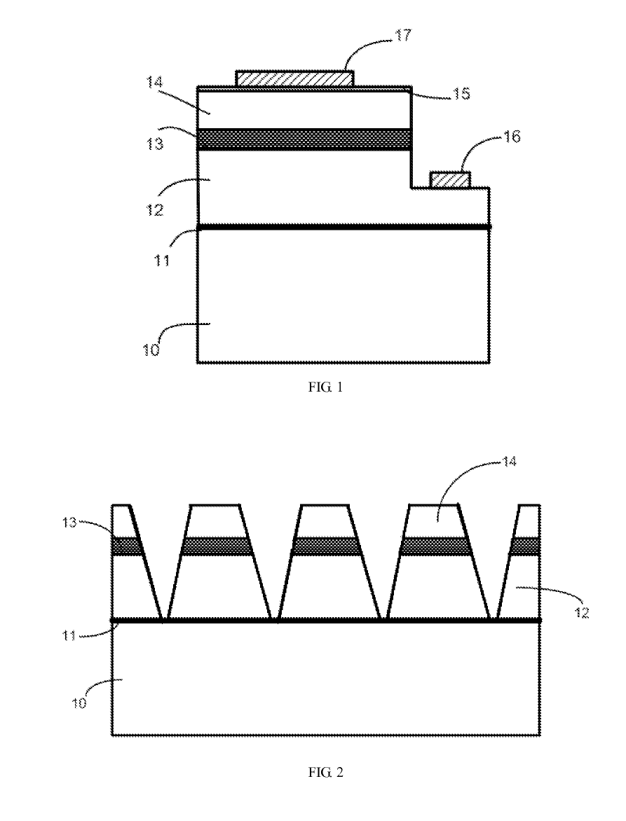

FIG. 1 shows a conventional GaN-based light-emitting diode. To obtain a high-quality epitaxial layer a buffer layer 11 is grown on a substrate 10, e.g. sapphire, SiC, silicon, and others. The n-type doped GaN layer 12, the active layer 13 and the p-type doped GaN layer 14 are grown in sequence. Generally a multiple well structure is provided as the active layer. Light is generated in the active region when electricity is applied to p-electrode 17 and n-electrode 16. A thin transparent p-electrical contact layer 15 deposited on the layer 14, which is good for the lateral spread of the current injected.

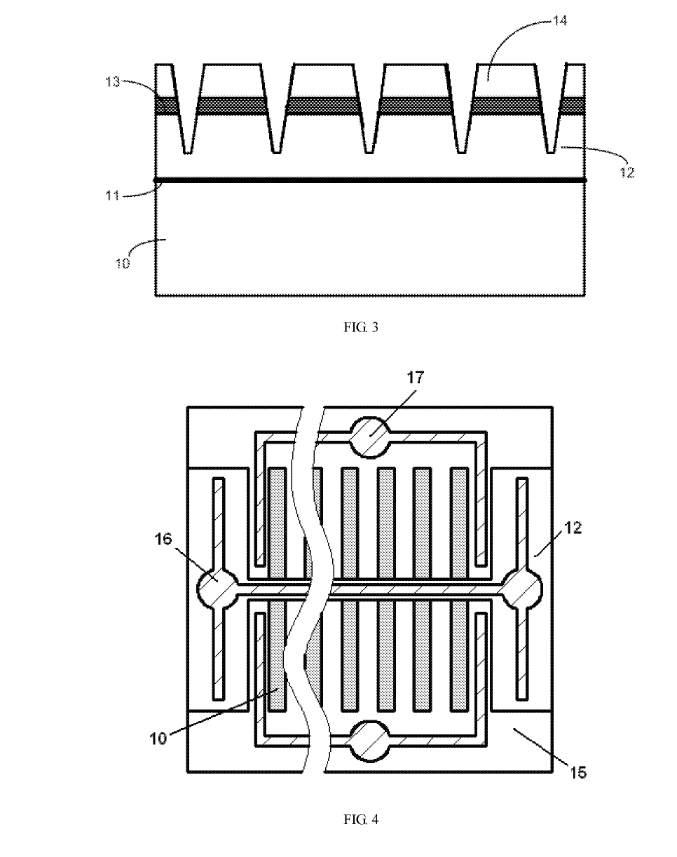

FIG. 2 shows a light-emitting diode with cleaved epitaxial layer. This structure could be easily realized through a lithography process and subsequent dry etching. The oblique angle of sidewalls of each micro-unit and the depth are dependent on processing parameters of dry etching, such as chamber pressure, power, and flux ratio of reactive gases. FIG. 3 is a schematic cross-section of a light-emitting diode of which the epitaxial layer is not cleaved to the substrate.

The fabrication process of an exemplary LED structure is described in the following. This structure is realized using a suitable fabrication process including sub-processes such as wafer cleaning, lithography, etching, dielectric deposition, metallization, and the like. First a layer of transparent, conductive material, for example indium-tin oxide (ITO) is deposited on the p-type doped GaN layer 14 as an electrical contact layer 15 to obtain a good current spreading. Then the epitaxial layer is cleaved to form a micro-trapeziform strips array through lithography and dry etching processes. The n-type doped GaN layer 12 is partially exposed by etching, and then p-electrode 17 and n-electrode 16 are deposited on the p-electrical contact layer 15 and the exposed n-type doped GaN layer 12 respectively. The completed structure in this example is shown in FIG. 4.

Microstructures can be made on the top surface of LED chip shown in FIG. 4 to help more light escape outside. The structured top surface requires a thicker top p-type doped GaN layer, which could not be achieved because of the relatively high resistivity of p-type doped GaN. Besides, some treatments such as dry etching may cause electrical deterioration. In the present invention a light extraction layer 18 is introduced by thin film deposition processing using chemical vapor deposition (CVD) or sputtering deposition techniques on the p-type doped GaN layer 14. The material of the light extraction layer should have high-refractive index and be transparent to make sure the light generated in the active layer 13 can get into this layer, and SiC is a preferable choice. The appropriate depth of the layer is several microns. A schematic cross-section of an LED chip introducing a light extraction layer with microstructures is shown in FIG. 5.

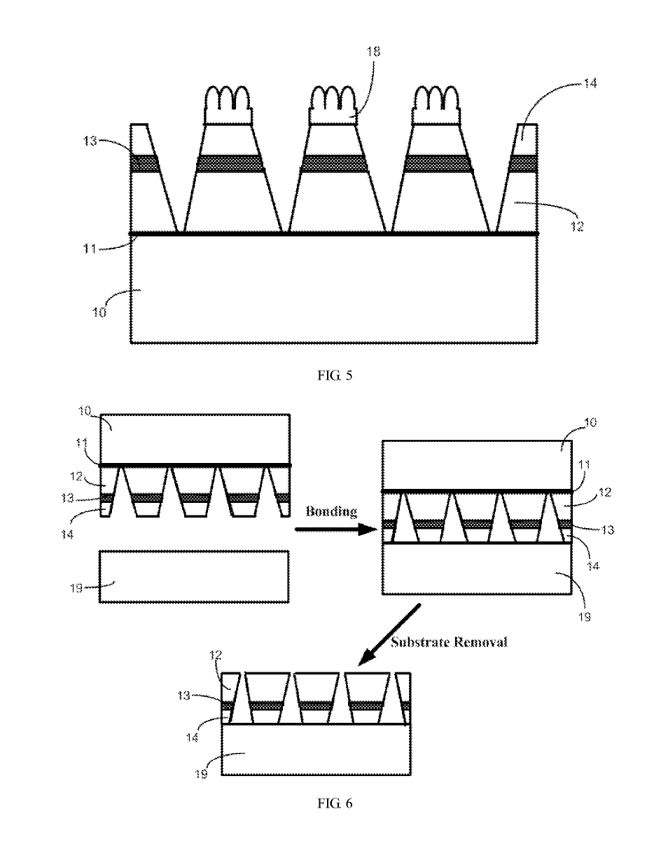

As we can see in FIG. 6, utilizing wafer bonding technology and lift-off method, an n-side-up LED structure can be obtained. First the epitaxial layer is cleaved using lithography and dry etching, just as mentioned above. Then the wafer is flipped and bonded to a new conductive substrate e.g. Si. Subsequently the substrate of the epitaxial layer is removed by lift-off technology. Recently the laser-life-off method has been applied extensively for detaching a sapphire substrate from a GaN film grown on it.

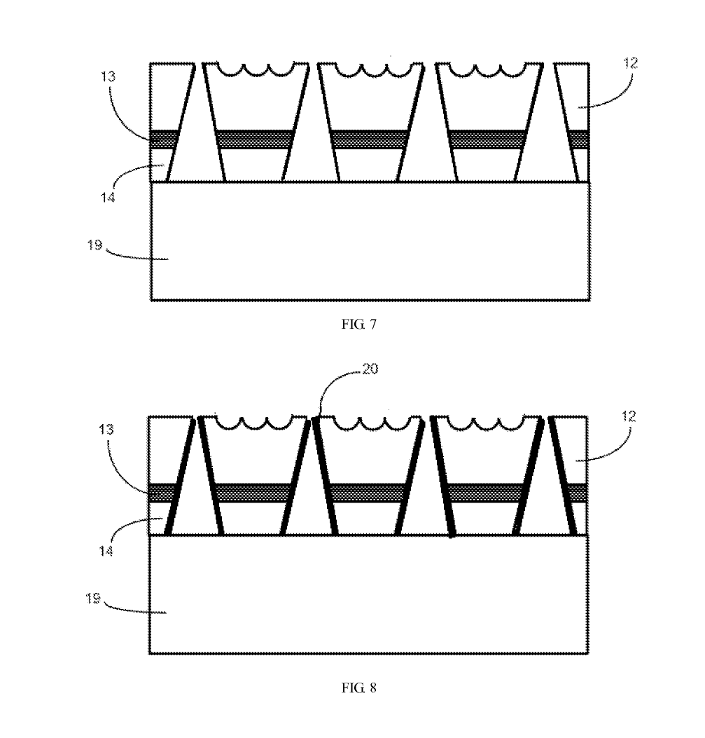

It is more convenient to make microstructures on the top surface of the n-side-up LED compared with the p-side-up one, since the thickness of the n-type doped GaN layer 12 generally is two or more microns. Microstructures can be made directly on the top n-type doped GaN layer 12. This approach may cause the current spreading to deteriorate, since the n-type doped GaN layer 12 is fragmented by the structuring. In addition, a light extraction can be introduced on this n-side-up LED structure, just as mentioned above. The n-side-up LED structure with microstructures on the top n-type doped GaN layer is shown in FIG. 7.

To some extent, the light escaping out the lateral surfaces of each micro-unit will enter into the adjacent micro-units and never escape. One method to overcome this problem is to deposit one reflected film on the lateral surface. FIG. 8 shows a cross-section of LED structure wherein sidewalls of each segregated micro-unit are reflective.

The shape of one single micro-unit can take some feasible forms, such as trapeze strip, truncated pyramid, truncated cone, cube and the like. FIG. 9 schematically illustrates an embodiment of truncated pyramid shape.

The geometric parameters relative to the shape of the truncated pyramids should be optimized to gain better light output. Optimized parameter ranges for truncated pyramids are presented below. L describes the length of side of the top surface and θ describes the angle between the vertical line and the sidewall.

The best results are obtained with the following parameter ranges based on the ray-tracing simulations:

3 μm≦L≦30 μm

20°≦θ≦35°

Especially good values for the light extraction efficiency gained when given L=20 μm, θ=33°.

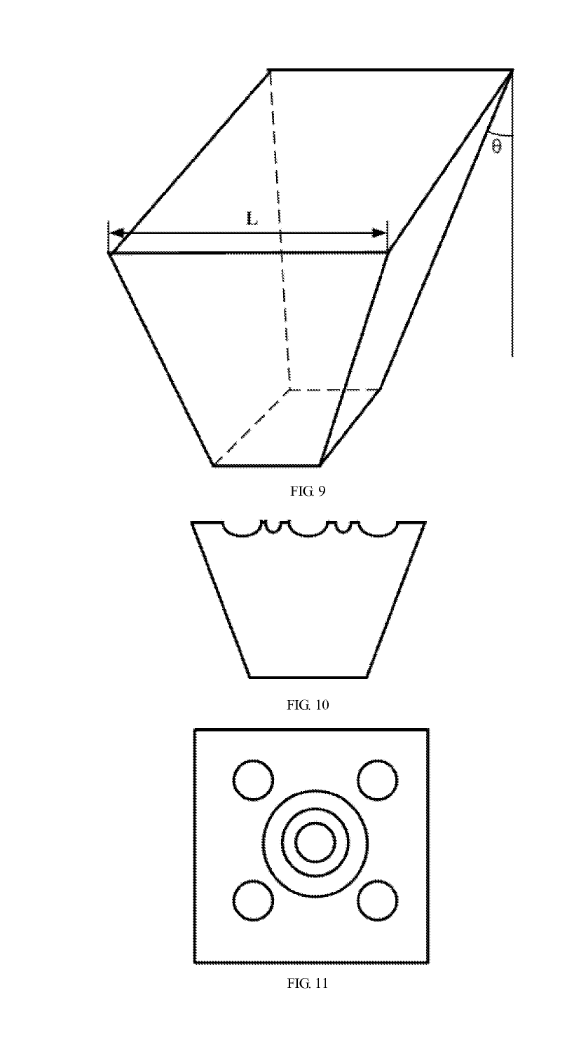

The conceivable shapes of microstructure include regular micro-lens array, pyramids array, cones array, tetrahedrons array, concave tapers, concave torus, concave cylinder and the like. According to the ray-tracing simulations, concave spherical surface, concave torus, concave cylinder, concave tapers or combinations of these shapes are relatively effective, when the shape of one single micro-unit is a truncated pyramidal. FIG. 10 and FIG. 11 show a cross-section and top view of an alternative embodiment of microstructures on one single micro-unit respectively.

It is contemplated that features disclosed in this application, as well as those described in the above applications incorporated by reference, can be mixed and matched to suit particular circumstances. Various other modifications and changes will be apparent to those of ordinary skill.

1. A light-emitting diode, comprising a substrate and an epitaxial layer formed on said substrate, said epitaxial layer including a buffer layer grown on said substrate, an n-contact layer grown on said a buffer layer, an active layer for generating light grown on said an n-contact layer and a p-contact layer grown on said active layer, said epitaxial layer cleaved into micro-units to suppress light transverse propagation, a light extraction layer deposited on said epitaxial layer, wherein the top surface of said light extraction layer has microstructures to improve the light output, wherein said light extraction layer material has high refractive-index and is transparent, and wherein a thickness of said light extraction layer is greater than 2 microns.

2. The light-emitting diode according to claim 1 wherein said the epitaxial structure can be any practical and reasonable layer structure designs of a light-emitting diode.

3. The light-emitting diode according to claim 1 wherein said micro-units can take any conceivable form, such as trapeze strips array, truncated pyramids array, truncated cones array, cubes array, certain free-form optics array and the like.

4. The light-emitting diode according to claim 1 wherein feasible shapes of said microstructures include micro-lens array, pyramids array, cones array, tetrahedrons array, concave tapers, concave torus, concave cylinder, certain free-form optics array and the like.

5. The light-emitting diode according to claim 1 wherein microstructures are made on the top surface of said p-contact layer.

6. The light-emitting diode according to claim 4 wherein feasible shapes of said microstructures include micro-lens array, pyramids array, cones array, tetrahedrons array, concave tapers, concave torus, concave cylinder, certain free-form optics array and the like.

7. The light-emitting diode according to claim 1 wherein after said epitaxial layer is cleaved, said light-emitting diode is bonded to another new substrate, and then the former substrate is removed.

8. The light-emitting diode according to claim 6 wherein microstructures are made on the top surface of said n-contact layer.

9. The light-emitting diode according to claim 7 wherein feasible shapes of said microstructures include micro-lens array, pyramids array, cones array, tetrahedrons array, concave tapers, concave torus, concave cylinder, certain free-form optics array and the like.

10. The light-emitting diode according to claim 6 wherein a light extraction layer is deposited on said n-contact layer.

11. The light-emitting diode according to claim 9 wherein microstructures are made on the top surface of said light extraction layer.

12. The light-emitting diode according to claim 10 wherein feasible shapes of said microstructures include micro-lens array, pyramids array, cones array, tetrahedrons array, concave tapers, concave torus, concave cylinder, certain free-form optics array and the like.

13. The light-emitting diode according to claim 1 wherein a reflected film is deposited on the sidewalls of said micro-units.

14. The light-emitting diode according to claim 1 wherein a new material is embedded into the gaps between said micro-units.

15. The light-emitting diode according to claim 13 wherein said new material has low refractive index.

16. The light-emitting diode according to claim 1 wherein the shapes and oblique angles of the sidewalls of said micro-units are designed to form total reflection on the sidewalls.

17. The light-emitting diode according to claim 1 wherein the depth of cleaving is not constant.

18. The light-emitting diode according to claim 1 is flip-chip bonded to another conductive substrate.
